(19) United States
(12) Patent Application Publication
(10) Pub. No.: US 2010/0279014 A1
(43) Pub. Date: Nov. 4, 2010

(54) VACUUM PROCESSING APPARATUS, VACUUM PROCESSING METHOD, AND COMPUTER READABLE STORAGE MEDIUM

(75) Inventor: Tsutomu Hiroki, Yamanashi (JP)

Correspondence Address: IPUSA, P.L.L.C, 1054 31ST STREET, N.W., Suite 400, Washington, DC, 20007, US

(73) Assignee: TOKYO ELECTRON LIMITED, Minato-ku, Tokyo (JP)

(21) Appl. No.: 12/810,525

(22) PCT Filed: Dec. 17, 2008
(86) PCT No.: PCT/JP2008/072930

§ 371 Date: Jun. 25, 2010

(30) Foreign Application Priority Data
Dec. 28, 2007 (JP) 2007-339987

(51) Int. Cl. B05D 3/00; C23C 14/00

(52) U.S. Cl. 427/294; 118/50

(57) ABSTRACT

A disclosed vacuum processing apparatus comprises a preliminary vacuum chamber whose inner pressure is switchable between a normal pressure and a reduced pressure, wherein a substrate is transferred to or from the preliminary vacuum chamber; plural vacuum processing chambers, wherein corresponding processes are carried out with respect to the substrate; a vacuum transfer chamber to which the preliminary vacuum chamber and the plural vacuum processing chambers are connected, the vacuum transfer chamber including a substrate transfer mechanism that transfers the substrate between the preliminary vacuum chamber and the plural vacuum processing chambers, and a concave portion formed in a bottom portion or a ceiling portion of the vacuum transfer chamber; an auxiliary module, wherein a predetermined process is carried out with respect to the substrate transfer mechanism; and an elevation mechanism that moves the auxiliary module between a first position where the auxiliary module is accommodated in the concave portion so that the auxiliary module does not hinder the substrate transfer mechanism from transferring the substrate, and a second position where the substrate may be transferred to or from the auxiliary module by the substrate transfer mechanism.

### TECHNICAL FIELD

The present invention relates to a vacuum processing apparatus that is configured with plural vacuum chambers connected to a vacuum transfer chamber having a substrate transfer unit, thereby enabling efficient usage of the plural vacuum chambers; a vacuum process method employing the vacuum processing apparatus; and a computer readable storage medium storing a computer that causes the vacuum processing apparatus to carry out the vacuum process method.

### BACKGROUND ART

In semiconductor device fabrication, a semiconductor wafer (referred to as a wafer hereinafter) serving as a semiconductor substrate undergoes predetermined vacuum processes including an etching process, a film deposition process, an ashing process and the like. As an apparatus where these processes are carried out, a so-called multi-chamber vacuum processing apparatus has been known where plural vacuum processing chambers are connected to a common transfer chamber that can be maintained at vacuum, and this vacuum transfer chamber is connected to an atmospheric transfer chamber via a load lock chamber serving as a preliminary vacuum chamber.

Such a vacuum processing chamber is shown in FIG. 1. In this apparatus, a wafer in a carrier 10 is received by a first transfer arm 12 in an atmospheric transfer chamber 11 and transferred by the first transfer arm 12 to a preliminary vacuum chamber 13 maintained at an atmospheric pressure. Next, after the preliminary vacuum chamber 13 is evacuated to a predetermined reduced pressure, the wafer is transferred by a second transfer arm 14 through a vacuum transfer chamber 15 to any one of vacuum chambers 16 where the wafer undergoes predetermined processes. Then, the wafer is transferred by the second transfer arm 14 to the preliminary vacuum chamber 13 maintained at vacuum through the vacuum transfer chamber 15. After the preliminary vacuum chamber 13 is pressurized to the atmospheric pressure, the wafer is transferred by the first transfer arm 12 to the carrier 10 through the transfer chamber 11.

In this case, the second transfer arm 14 has two holding arms, which makes it possible to transfer a wafer out from the vacuum processing chamber 16 using one of the holding arms, subsequently to transfer an unprocessed wafer into the vacuum processing chamber 16 using the other one of the holding arms, and to transfer the wafer held by the one of the holding arms to another vacuum processing chamber 16 where the next process is carried out.

In such a vacuum processing apparatus, because the vacuum processing chambers 16 are arranged along a longitudinal direction of a transfer route of the vacuum transfer chamber 15, the number of the process chambers 16 provided in the vacuum processing apparatus is determined in accordance with the length of the vacuum transfer chamber 15. In the vacuum processing apparatus as it now stands, up to 6 vacuum processing chambers 16 are provided as shown in the drawing, and a series of processes such as an etching process, a film deposition process, and an asking process are carried out in the corresponding chambers in order to fabricate semiconductor devices.

Incidentally, it has been required that a module where an arm cleaning process is carried out, a module where a degassing process or the like for vaporizing substances attached on a wafer in order to remove such substances is carried out, and an area where the wafer is temporarily placed, in addition to the chambers for the etching process or the like, be provided so that the second transfer arm 14 can access these modules and the area in the above vacuum processing apparatus.

The arm cleaning process is carried out in order to clean a wafer holding area of the second transfer arm 14. When the second transfer arm 14 enters the vacuum transfer chamber 16, a remaining process gas in the vacuum processing chamber 16 is adsorbed on the second transfer arm 14, and thus a film is deposited on the second transfer arm 14 when the second transfer arm 14 repeatedly enters the vacuum processing chamber 16. Because the film may be peeled off to fall on the wafer, the film deposited on the second transfer arm 14 may cause particle contamination. In order to reduce such contamination, it is effective to clean the second transfer arm 14, and thus the module where the arm cleaning process is carried out is necessary.

In addition, the area where the wafer is temporarily placed may be necessary when an interior of the vacuum processing chamber 16 is being cleaned after the wafer is transferred out by the second transfer arm 14 from the vacuum processing chamber 16. As stated above, one of the two holding arms holds the wafer that has been processed in the vacuum processing chamber 16, and the other one of the holding arms holds a wafer to be processed (an unprocessed wafer). When the vacuum processing chamber 16 is being cleaned, the unprocessed wafer cannot be transferred into the vacuum processing chamber 16. In this case, the second transfer arm 14 cannot transfer the processed wafer into the next vacuum processing chamber 16, and thus the second transfer arm 14 has to be on standby while holding the two wafers until the cleaning process is completed. At this time, if the unprocessed wafer is temporarily placed in the area, the processed wafer can be transferred into the next step vacuum processing chamber 16, thereby avoiding a reduced throughput. For this reason, the area where a wafer is temporarily placed (referred to as a buffer module, in some cases, hereinafter) becomes necessary.

However, because the modules where fabrication processes for fabricating semiconductor devices are preferentially connected to the vacuum transfer chamber 15, it is difficult to set aside spaces for auxiliary modules such as the arm cleaning module, the degassing process module, and the buffer module, which are used between the fabrication processes, in the vacuum processing apparatus at it now stands.

In order to address such difficulty, it may be thought that the vacuum transfer chamber 15 may be enlarged, thereby increasing the number of the modules that can be connected to the vacuum transfer chamber 15, so that the auxiliary modules are connected to the vacuum transfer chamber 15. However, such a configuration may result in an increased occupying area (footprint), and an increased moving area of the second transfer arm 14, which reduces throughput. In addition, when the vacuum transfer chamber 15 is enlarged in order to increase the number of the modules to be connected, a problem is caused in that the apparatus as a whole and the second transfer arm 14 have to be greatly modified in terms of their specifications, which requires time and effort in designing and the like. Moreover, although it is thought that the auxiliary modules are to be provided in the preliminary chamber 13, complicated pressure control is necessary when the preliminary chamber 13 is selectively maintained at vacuum or an atmospheric pressure, and thus such complicated pressure control may reduce throughput.

Furthermore, the arm cleaning module and the buffer modules are not always used, but used at a predetermined timing, and rather, may not be used for a long time. Therefore, from a viewpoint of designing the apparatus and a transferring program, a series of processes for fabricating semiconductor devices are preferably carried out using the currently available transferring program in the vacuum processing apparatus as it now stands. Upon such request, the inventors of this invention have investigated a configuration that enables the auxiliary modules to be added while keeping changes in an apparatus configuration and programs as they now stand to the minimum.

Incidentally, Patent Document 1 proposes that simple processes such as a degassing process and a predetermined measurement can be carried out at a buffer portion provided in a vacuum transfer chamber. However, because the buffer portion is provided in a moving area of the transfer unit in the vacuum transfer chamber in such a configuration, the transfer unit cannot slide along a longitudinal direction of the vacuum transfer chamber.

Therefore, two transfer units need to be provided in different areas in order to transfer the wafer to all the vacuum processing chambers connected to the vacuum transfer chamber. Namely, because the buffer portion and the two transfer units need to be provided in the vacuum transfer chamber, specifications different from the specifications of the vacuum processing chamber as it now stands are required, and the footprint inevitably becomes larger. Therefore, the problems to be solved by the present invention cannot be solved by the configuration disclosed in Patent Document 1.

Patent Document 1: Japanese Patent Application Laid-Open Publication No. 2002-324829.

### SUMMARY OF INVENTION

### Problems to be Solved by the Invention

The present invention has been made in view of the above, and is directed to a vacuum processing apparatus to which an auxiliary module for carrying out a process for a substrate transfer unit, a process for a substrate, a queuing of a substrate, or the like can be added without an increased footprint of the apparatus; a vacuum processing method employing the vacuum processing apparatus; and a program that causes the vacuum processing apparatus to execute the vacuum processing method.

### Means of Solving the Problems

In order to solve the above problem, a first aspect of the present invention provides a vacuum processing apparatus comprising a preliminary vacuum chamber whose inner pressure is switchable between a normal pressure and a reduced pressure, wherein a substrate is transferred to or from the preliminary vacuum chamber; plural vacuum processing chambers, wherein corresponding processes are carried out with respect to the substrate; a vacuum transfer chamber to which the preliminary vacuum chamber and the plural vacuum processing chambers are connected, the vacuum transfer chamber including a substrate transfer mechanism that transfers the substrate between the preliminary vacuum chamber and the plural vacuum processing chambers, and a concave portion formed in a bottom portion or a ceiling portion of the vacuum transfer chamber; an auxiliary module, wherein a predetermined process is carried out with respect to the substrate transfer mechanism; and an elevation mechanism that moves the auxiliary module between a first position where the auxiliary module is accommodated in the concave portion so that the auxiliary module does not hinder the substrate transfer mechanism from transferring the substrate, and a second position where the substrate may be transferred to or from the auxiliary module by the substrate transfer mechanism.

A second aspect of the present invention provides a vacuum processing apparatus according to the first aspect, wherein the predetermined process carried out with respect to the substrate transfer mechanism is any one of a cleaning process for a holding arm of the substrate transfer mechanism, the holding arm holding the substrate; a static electricity removal process for the holding arm; and a position adjustment process for the holding arm.

A third aspect of the present invention provides a vacuum processing apparatus comprising a preliminary vacuum chamber whose inner pressure is switchable between a normal pressure and a reduced pressure, wherein a substrate is transferred to or from the preliminary vacuum chamber; plural vacuum processing chambers, wherein corresponding processes are carried out on the substrate; a vacuum transfer chamber to which the preliminary vacuum chamber and the plural vacuum processing chambers are connected, the vacuum transfer chamber including a substrate transfer mechanism that transfers the substrate between the preliminary vacuum chamber and the plural vacuum processing chambers, and a concave portion formed in a bottom portion or a ceiling portion of the vacuum transfer chamber; an auxiliary module that may accommodate the substrate, wherein a predetermined process is carried out with respect to the substrate accommodated therein; and an elevation mechanism that moves the auxiliary module between a first position where the auxiliary module is accommodated in the concave portion so that the auxiliary module does not hinder the substrate transfer mechanism from transferring the substrate, and a second position where the substrate may be transferred to or from the auxiliary module by the substrate transfer mechanism.

A fourth aspect of the present invention provides a vacuum processing apparatus according to the third aspect, wherein the auxiliary module comprises a lid body that is movable upward and downward between a third position where the concave portion is closed in an airtight manner and a fourth position where the lid body is projected into the vacuum transfer chamber by the elevation mechanism; and a substrate receiving portion on which the substrate is placed, wherein the substrate receiving portion is movable upward and downward between a fifth position where the substrate is placed in the substrate receiving portion in a space defined by the concave portion and the lid body, and a sixth portion where the substrate is transferred between the substrate transfer mechanism and the substrate receiving portion.

A fifth aspect of the present invention provides a vacuum processing apparatus according to the fourth aspect, wherein the substrate receiving portion is moved upward or downward along with the lid body in an integrated manner.

A sixth aspect of the present invention provides a vacuum processing apparatus according to the third aspect, wherein the auxiliary module includes a lid body that is movable upward and downward between a third position where the concave portion is closed in an airtight manner and a fourth position where the lid body is projected into the vacuum transfer chamber by the elevation mechanism; a substrate receiving portion arranged on a space defined by the concave portion and the lid body that closes the concave portion in an airtight manner, wherein the substrate is placed on the substrate receiving portion; a transfer-in/out portion configured to be movable upward and downward so that the substrate may be transferred between the substrate receiving portion and the substrate transfer mechanism.

A seventh aspect of the present invention provides a vacuum processing apparatus according to any one of the fourth through the sixth aspects, wherein the auxiliary module comprises a process portion that carries out a process with respect to the substrate.

An eighth aspect of the present invention provides a vacuum processing apparatus according to the seventh aspect, wherein the process portion that carries out a process with respect to the substrate is a temperature control portion that controls a temperature of the substrate.

A ninth aspect of the present invention provides a vacuum processing apparatus according to the eighth aspect, wherein the auxiliary module includes a heating portion that heats the substrate.

A tenth aspect of the present invention provides a vacuum processing apparatus according to the eighth aspect, wherein the auxiliary module includes a cooling portion that cools the substrate.

An eleventh aspect of the present invention provides a vacuum processing apparatus according to the eighth aspect, wherein the temperature control portion comprises a flow passage of a temperature control fluid, formed in a wall portion of the concave portion; a gas supplying portion that supplies gas to a space defined by the concave portion and the lid body that closes the concave portion in an airtight manner; and an evacuation portion that evacuates the space to vacuum.

A twelfth aspect of the present invention provides a vacuum processing apparatus according to the eleventh aspect, wherein a substance attached on the substrate is removed by vaporizing the substance attached on the substrate.

A thirteenth aspect of the present invention provides a vacuum processing apparatus according to the first aspect, wherein the substrate transfer mechanism comprises a pedestal provided in the vacuum transfer chamber in order to be movable along a guide rail provided in the vacuum transfer chamber; and a holding arm for the substrate, the holding arm being provided in the pedestal in order to be rotatable and movable to and fro in a horizontal direction, wherein a concave portion formed in a bottom portion of the vacuum transfer chamber may be arranged in an area where the concave portion does not interfere with the guide rail so that the pedestal does not interfere with the concave portion.

A fourteenth aspect of the present invention provides a vacuum processing method executed in the vacuum processing apparatus according to the first aspect, the vacuum processing method comprising the steps of accommodating the auxiliary module in the concave portion; transferring the substrate into one vacuum processing apparatus among the plural vacuum processing chambers using the substrate transfer mechanism; carrying out a predetermined vacuum process with respect to the substrate in the one vacuum processing chamber; causing the auxiliary module to project into the vacuum transfer chamber from the concave portion and moving the substrate transfer mechanism into the auxiliary module; and carrying out the predetermined process with respect to the substrate transfer mechanism in the auxiliary module.

A fifteenth aspect of the present invention provides a vacuum processing method according to the fourteenth aspect, wherein any one of a cleaning process for a holding arm of the substrate transfer mechanism, the holding arm holding the substrate; a static electricity removal process for the holding arm; and a position adjustment process for the holding arm is carried out in the step of carrying out a predetermined process with respect to the substrate transfer mechanism in the auxiliary module.

A sixteenth aspect of the present invention provides a vacuum processing method executed in the vacuum processing apparatus according to the third aspect, the vacuum processing method comprising the steps of accommodating the auxiliary module in the concave portion; transferring the substrate into one vacuum processing apparatus among the plural vacuum processing chambers using the substrate transfer mechanism; carrying out a predetermined vacuum process with respect to the substrate in the one vacuum processing chamber; causing the auxiliary module to project into the vacuum transfer chamber from the concave portion and moving the substrate transfer mechanism into the auxiliary module; and accommodating in the concave portion the auxiliary module to which the substrate is transferred.

A seventeenth aspect of the present invention provides a vacuum processing method according to the sixteenth aspect, wherein the step of moving the substrate transfer mechanism into the auxiliary module is carried out when an arbitrary vacuum processing chamber among the plural vacuum processing chambers is cleaned.

An eighteenth aspect of the present invention provides a vacuum processing method according to the sixteenth aspect of the present invention, further comprising a step of carrying out the predetermined vacuum process with respect to the substrate in the auxiliary module accommodated in the concave portion.

A nineteenth aspect of the present invention provides a vacuum processing method according to the eighteenth aspect, wherein a temperature of the substrate is adjusted in the step of carrying out the predetermined vacuum process with respect to the substrate in the auxiliary module.

A twentieth aspect of the present invention provides a vacuum processing method according to the eighteenth aspect, wherein a substance attached on the substrate is removed by vaporizing the substance attached on the substrate in the step of carrying out the predetermined vacuum process with respect to the substrate in the auxiliary module.

A twenty-first aspect of the present invention provides a computer readable storage medium storing a computer program that causes the vacuum processing apparatus according to the first aspect to execute a vacuum processing method, the computer program comprising steps in order to execute the steps of accommodating the auxiliary module in the concave portion; transferring the substrate into one vacuum processing apparatus among the plural vacuum processing chambers using the substrate transfer mechanism; carrying out a predetermined vacuum process with respect to the substrate in the one vacuum processing chamber; causing the auxiliary module to project into the vacuum transfer chamber from the concave portion and moving the substrate transfer mechanism into the auxiliary module; and carrying out the predetermined process with respect to the substrate transfer mechanism in the auxiliary module.

A twenty-second aspect of the present invention provides a computer readable storage medium storing a computer program that causes the vacuum processing apparatus according to the third aspect to execute a vacuum processing method, the computer program comprising steps in order to execute the steps of accommodating the auxiliary module in the concave portion; transferring the substrate into one vacuum processing apparatus among the plural vacuum processing chambers using the substrate transfer mechanism; carrying out a predetermined vacuum process with respect to the substrate in the one vacuum processing chamber; causing the auxiliary module to project into the vacuum transfer chamber from the concave portion and moving the substrate transfer mechanism into the auxiliary module; and accommodating in the concave portion the auxiliary module to which the substrate is transferred.

### EFFECTS OF THE INVENTION

According to the present invention, because a concave portion is formed in a bottom portion or a ceiling portion of a vacuum transfer chamber, and an auxiliary module for carrying out a process fora substrate transfer mechanism, a queuing of a substrate, a process for a substrate, or the like is accommodated in the concave portion when not in use in order not to interfere with substrate transfer by a substrate transfer mechanism, and is projected into the vacuum transfer chamber when in use, the auxiliary module can be added without an increased footprint of the apparatus.

In addition, the concave portion formed in the bottom portion or the ceiling portion of the vacuum transfer chamber, and a lid body that closes an opening of the concave portion form a partitioned space where the queuing of the substrate and the process for the substrate may be carried out, thereby obtaining a function of the queuing of the substrate and the substrate process without an increased footprint of the apparatus.

### BRIEF DESCRIPTION OF THE DRAWINGS

FIG. 1 is a plan view illustrating a related art vacuum processing apparatus.

FIG. 2 is a plan view illustrating a vacuum processing apparatus according to an embodiment of the present invention.

FIG. 3 is a cross-sectional view illustrating an example of a second transfer chamber provided in the vacuum processing apparatus.

FIG. 4 is a cross-sectional view illustrating an example of the second transfer chamber.

FIG. 5 is a perspective view illustrating an example of a primary portion of the second transfer chamber.

FIG. 6 is a perspective view illustrating an example of the primary portion of the second transfer chamber.

FIG. 7 is a perspective view illustrating an example of the primary portion of the second transfer chamber.

FIG. 8 is a cross-sectional view illustrating another example of the vacuum processing apparatus.

FIG. 9 is a cross-sectional view illustrating yet another example of the vacuum processing apparatus.

FIG. 10 is a cross-sectional view illustrating yet another example of the vacuum processing apparatus.

FIG. 11A is a process drawing for explaining an operation of the vacuum processing chamber shown in FIG. 10.

FIG. 11B is a process drawing for explaining an operation of the vacuum processing chamber shown in FIG. 10.

FIG. 12A is a process drawing for explaining an operation of the vacuum processing chamber shown in FIG. 10.

FIG. 12B is a process drawing for explaining an operation of the vacuum processing chamber shown in FIG. 10.

FIG. 13 is a process drawing for explaining an operation of the vacuum processing chamber shown in FIG. 10.

FIG. 14 is a cross-sectional view illustrating another example of a vacuum processing apparatus.

FIG. 15 is a cross-sectional view illustrating another example of a vacuum processing apparatus.

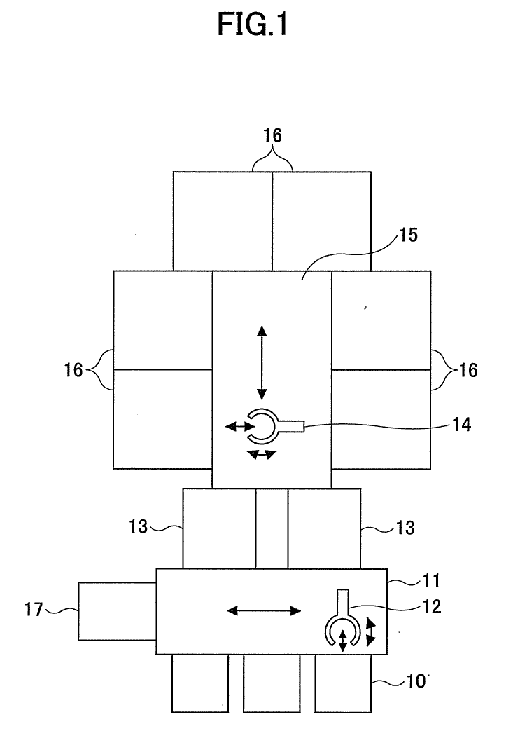

### DESCRIPTION OF THE REFERENCE NUMERALS

C carrier
21 first transfer chamber
22, 23 load lock chamber (preliminary vacuum chamber)
3 second transfer chamber
30 bottom portion
31A through 31F vacuum processing chamber
32 second transfer arm
34 pedestal
37 guide rail
38 first concave portion
4 cleaning module
41 second concave portion
41b flow passage
6 buffer module
7, 8, 40, 82 lid body
71 holding member
87 elevation rod
W semiconductor wafer

### MODE(S) FOR CARRYING OUT THE INVENTION

Non-limiting, exemplary embodiments of the present invention will now be described with reference to the accompanying drawings. In the drawings, the same or corresponding reference symbols are given to the same or corresponding members or components, and repetitive explanations are omitted. It is to be noted that the drawings are illustrative of the invention, and there is no intention to indicate scale or relative proportions among the members or components. Therefore, the specific size should be determined by a person having ordinary skill in the art in view of the following non-limiting embodiments.

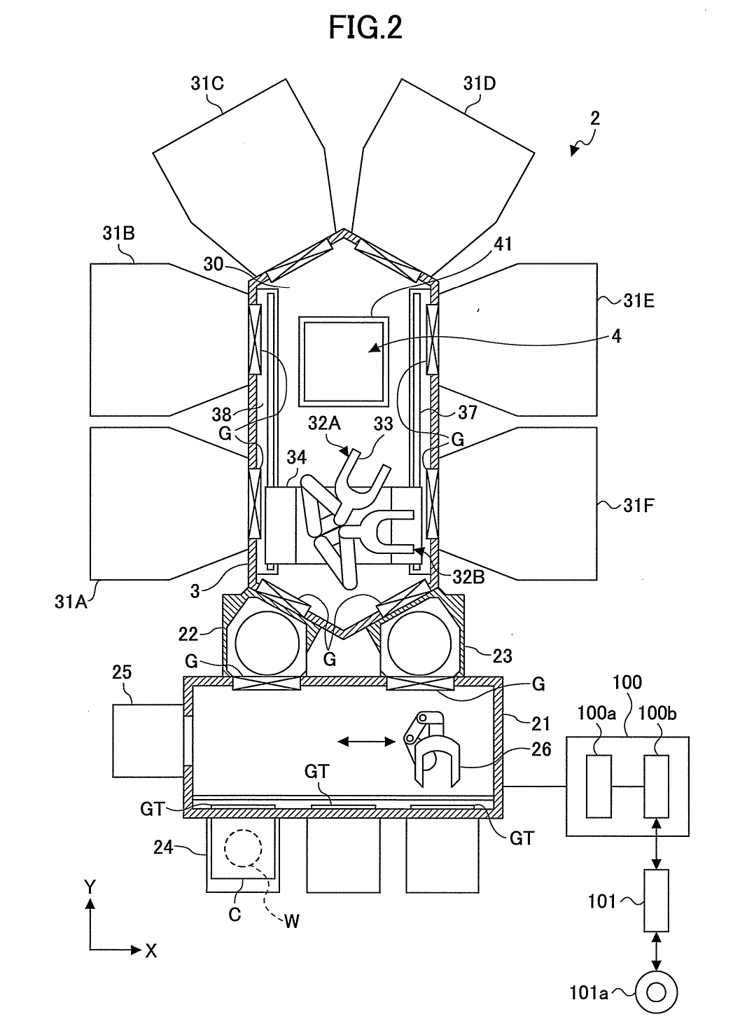

FIG. 2 is a plan view of an entire configuration of a vacuum processing apparatus 2. As shown, the vacuum processing apparatus 2 is provided with a first transfer chamber 21 serving as a loading module that loads or unloads a wafer W, load lock chambers (preliminary vacuum chambers) 22, 23, a second transfer chamber 3 serving as a vacuum transfer chamber, and vacuum processing chambers 31A through 31F. In addition, the vacuum processing apparatus 2 is provided, in front of (in a −Y direction in FIG. 2) the first transfer chamber 21, with a load port 24 on which a carrier C holding the wafer W is accommodated. In a front wall of the first transfer chamber 21, there is provided a gate door GT to which the carrier C placed on the load port 24 is connected. The gate door GT is opened or closed along with a lid of the carrier C.

On an outer wall of the first transfer chamber 21, there is provided an alignment chamber 25 where a direction and/or eccentricity of the wafer W is adjusted. The load lock chambers 22, 23 are provided with a vacuum pump and a leak valve, which are not shown. With this, the load lock chambers 22, 23 can be selectively maintained at vacuum or an atmospheric pressure. Namely, with such a configuration, a pressure difference between the load lock chambers 22, 23 and the first transfer chamber 21 under the atmospheric pressure and a pressure difference between the load lock chambers 22, 23 and the second transfer chamber 3 under vacuum can be eliminated, which allows the wafer W to be transferred between the first transfer chamber 21 and the second transfer chamber 3. Incidentally, “Gs” in FIG. 2 represent gate valves serving as partition walls that can be open or closed between the load lock chambers 22, 23 and the first transfer chamber 21, between the load lock chambers 22, 23 and the second transfer chamber 3, and between the second transfer chamber 3 and the vacuum processing chambers 31A through 31F.

In addition, the first transfer chamber 21 is provided with a first transfer arm 26. The first transfer arm 26 is, for example, movable in a direction along which the carriers C are arranged (in an X direction in FIG. 2), movable upward and downward, rotatable around a vertical axis, and movable to and fro in an X or Y direction, in order to transfer the wafer W between the carrier C and the load lock chambers 22, 23, and between the first transfer chamber 21 and the alignment chamber 25.

The second transfer chamber 3 has a top view shape of an elongated hexagon that extends along the X direction (FIG. 2). The load lock chambers 22, 23 are respectively coupled in an airtight manner with two sidewalls among the six sidewalls of the second transfer chamber 3, the two sidewalls being directed toward the −Y direction. The vacuum processing chambers 31A, 31B are coupled in an airtight manner with a sidewall of the second transfer chamber 3, the sidewall being directed toward the −X direction (referred to as a left wall, if necessary). The vacuum processing chambers 31E, 31F are coupled in an airtight manner with a sidewall of the second transfer chamber 3, the sidewall being directed toward the X direction (referred to as a right wall, if necessary). In addition, process chambers 31C, 31D are respectively coupled in an airtight manner with two sidewalls of the second transfer chamber 3, the sidewalls being directed toward the Y direction. For example, the vacuum processing chambers 31A through 31F may be a film deposition apparatus, an annealing apparatus, an etching apparatus or the like.

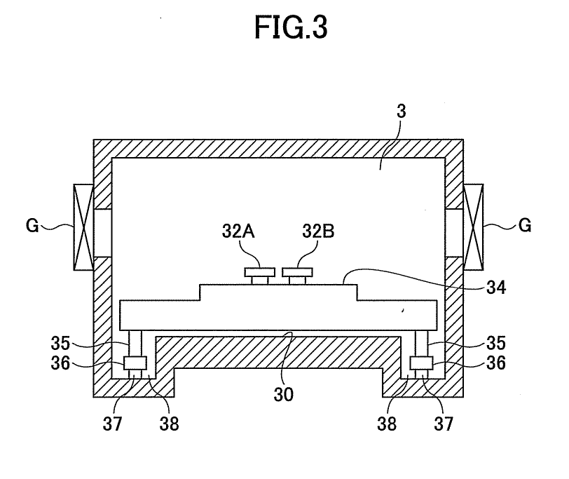

The second transfer chamber 3 is provided with second transfer arms 32 (32A, 32B) serving as a substrate transfer unit. With the second transfer arms 32, the wafer W is transferred between the load lock chambers 22, 23 and any of the vacuum processing chambers 31A through 31F. The second transfer arms 32A, 32B are arranged on a common pedestal 34 and include corresponding multi-joint arms that are rotatable around a vertical axis and expandable, and corresponding holding arms 33 that are attached at distal ends of the corresponding multi-joint arms and have a substantially U top view shape. Supporting parts 35 (FIG. 3) extending below are provided on a lower surface of and near peripheries of the pedestal 34 in the +/−X directions. The supporting parts 35 are coupled to a moving mechanism 36. With the moving mechanism 36, the pedestal 34 and thus the second transfer arms 32 can slide along guide rails 37 extending in the direction.

Referring to FIGS. 2 and 3, first concave portions 38 are formed in a bottom portion 30 of the second transfer chamber 3. The first concave portions 38 have an elongated square top view shape and extend along the corresponding left and right sidewalls in the Y direction. The guide rails 37 are arranged in the corresponding first concave portions 38. With such configurations, the second transfer arms 32 can slide along the +/−Y directions between a home position (the position shown in FIG. 2) near the load lock chambers 22, 23 in the second transfer chamber 3 and a position near the vacuum processing chambers 31C, 31D in the second transfer chamber 3.

Moreover, the second transfer chamber 3 is provided with an auxiliary module that can be moved substantially in a vertical direction. A second concave portion 41 having, for example, a square top view shape is formed in an area that becomes vacant when the second transfer arms 32 are positioned at the home position, namely an area on the +Y direction side of the second transfer chamber 3 and interiors of the two first concave portions 38. The auxiliary module is accommodated in the second concave portion 41. In the auxiliary module, a process for the second transfer arms 32 may be carried out, the wafer W may be temporarily placed, the wafer W may be processed, or the like. Specifically, the process carried out with respect to the second transfer arms 32 may include cleaning (arm cleaning), static electricity removal, position adjustment, temperature control, or the like with respect to the holding arms 33. In addition, the process carried out with respect to the wafer W may include degassing of substances attached on the wafer W, temperature control of the wafer W, preliminary heating of the wafer W before vacuum processes are carried out in the vacuum processing chambers 31A through 31F, cooling the wafer W after the vacuum processes are carried out, or the like.

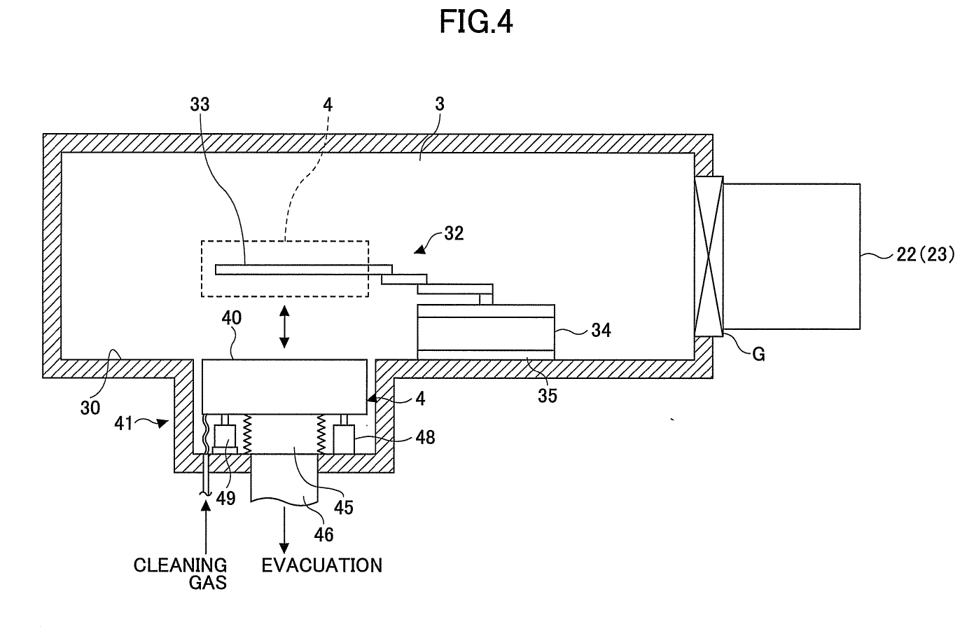

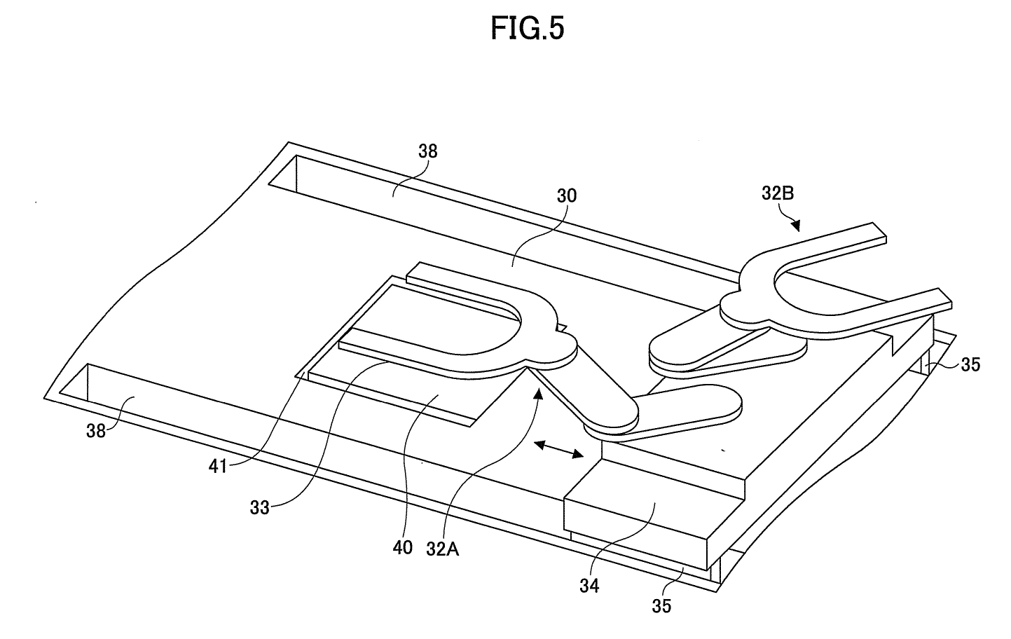

Next, a cleaning module 4 where the arm cleaning is carried out is explained as an example of the auxiliary module, with reference to FIGS. 4 through 7. The cleaning module 4 is used in order to clean wafer holding areas of the second transfer arms 32A, 32B. “40” in the drawings represents a chassis of the cleaning module 4. The chassis 40 has a shape of a flattened quadrangular prism having a square top view shape, and a size large enough to allow the holding arms 33 of the second transfer arms 32 to enter the interior of the chassis 40. In addition, the chassis 40 has an opening 42 open toward the load lock chambers 22, 23. The holding arms 33 of the second transfer arms 32 can move into or out from the interior of the chassis 40.

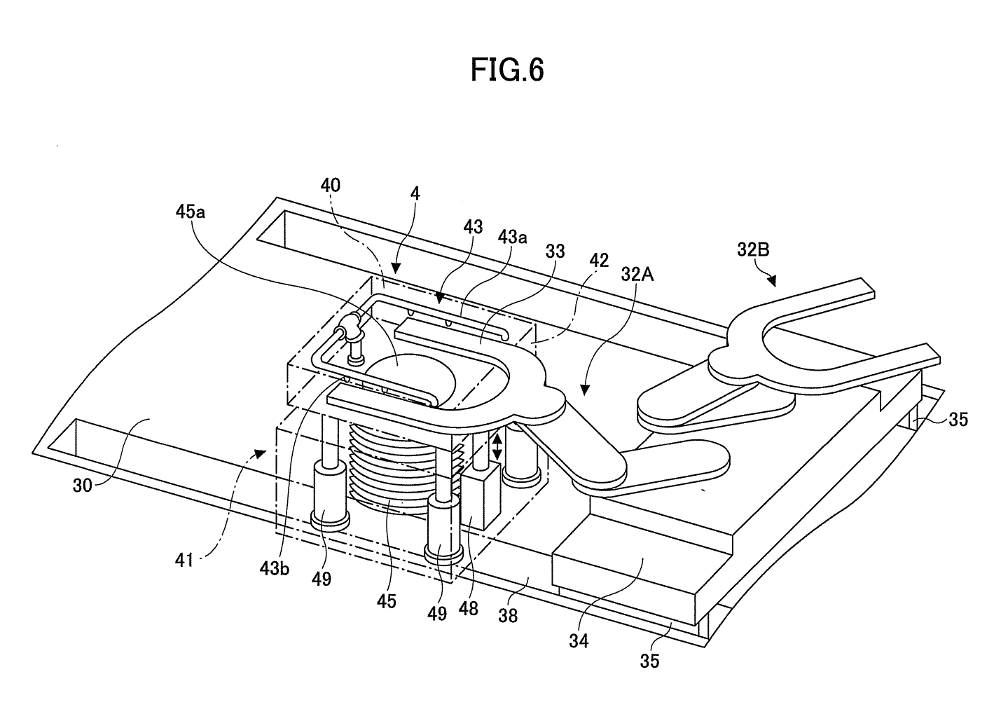

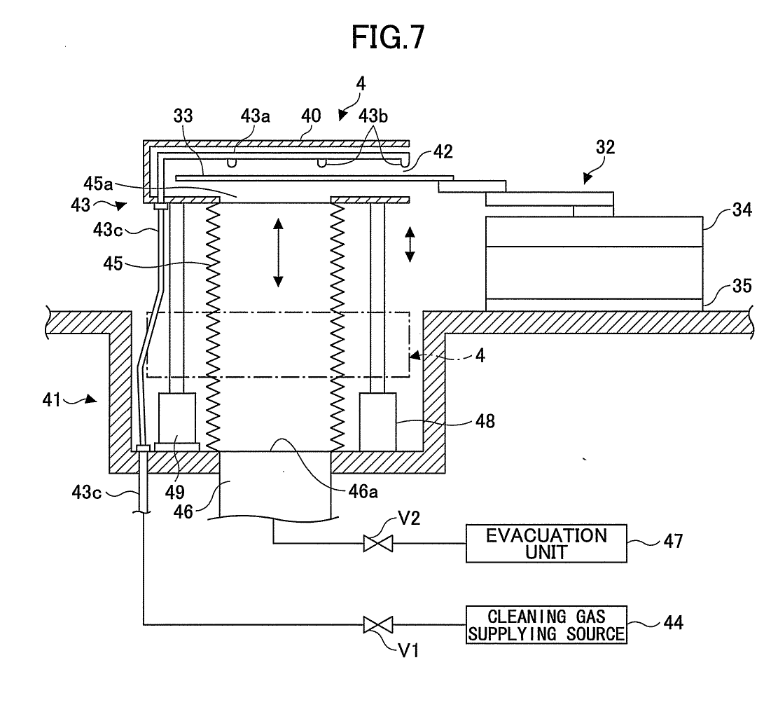

In the chassis 40, a cleaning gas supplying portion 43 (FIG. 6) for spraying a cleaning gas such as isopropyl alcohol gas toward the holding arms 33 is provided to be positioned above the holding arms 33 that move into the chassis 40. In order to supply the cleaning gas to the wafer holding areas of the holding arms 33, the cleaning gas supplying portion 43 includes cleaning gas supplying pipes 43a extending respectively along two arms of the holding arms 33, plural nozzle portions 43b provided at predetermined intervals along longitudinal directions of the cleaning gas supplying pipes 43a, and a cleaning gas supplying conduit 43c (FIG. 7) for supplying the cleaning gas to the cleaning gas supplying pipes 43a. The cleaning gas supplying conduit 43c is formed to be expandable, goes through a bottom portion of the second concave portion 41, and is connected to a cleaning gas supplying source 44 via a valve V1.

Referring to FIG. 7, an exhaust opening 45a is formed, for example, at a center portion of the bottom portion of the chassis 40. A bellows 45 extending downward below the chassis 40 and surrounding the exhaust opening 45a is connected to the exhaust opening 45a. The other end of the bellows 45 is connected to an exhaust opening 46a formed in the bottom portion of the second concave portion 41. The exhaust opening 46a is connected to an exhaust conduit 46, and the other end of the exhaust conduit 46 is connected to a vacuum evacuation unit 47 via a valve V2.

Such a chassis 40 is configured to be movable upward and downward between an accommodation position where the chassis 40 is accommodated in the second concave portion 41 and a process position where the holding arms 33 can move into or out from the chassis 40 in the second transfer chamber 3 (a position where the second transfer arms 32 are processed) due to an elevation mechanism 48 provided in the second concave portion 41. As the elevation mechanism 48, an air cylinder, an electrical actuator, or the like can be used. In addition, “49s” in FIGS. 6 and 7 represent elevation guides. Incidentally, the chassis 40 is accommodated in the second concave portion 41 so that an upper surface of the chassis 40 does not interfere with the pedestal 34 of the second transfer arm 3, when being in the accommodation position.

Referring again to FIG. 2, the vacuum processing apparatus 2 is provided with a control portion 100 composed of, for example, a computer. The control portion 100 includes a data processing portion 100a composed of a Central Processing Unit (CPU) and programs, and a memory portion 100b. Instructions that cause the control portion 100 to send control signals to constituent components of the vacuum processing apparatus 2 in order to execute transfer operations (each step) described later are incorporated in the programs. The programs are stored in a computer readable storage medium 101a such as a flexible disk, a compact disk, a hard disk drive, or a magneto-optical (MO) disk. The programs are installed into the memory portion 100b via an input/output device 101. In addition, control signals for opening/closing the gate valves G, driving the second transfer arms 32, elevating the cleaning module 4, and carrying out a predetermined process in the cleaning module 4 are sent to each portion of the second transfer chamber 3 by the control portion 100.

Next, a flow of the wafer W in the vacuum processing apparatus 2 is explained. First, the carrier C, which is a closed type, accommodating plural wafers is placed on the load port 24. A wafer W is transferred from the carrier C to the first transfer chamber 21 by the first transfer arm 26. Then, the gate valve G of the load lock chambers 22, 23 under an atmospheric pressure is opened, and the wafer W is transferred into the load lock chamber 22 or 23 by the first transfer arm 26. Next, after the load lock chamber 22 or 23 is evacuated to a predetermined reduced pressure, the gate valve G is opened and then the wafer W is transferred into the second transfer chamber 3 by the second transfer arm 32. Subsequently, the wafer W is transferred into any one of the vacuum processing chambers 31A through 31F, and undergoes a predetermined process in the vacuum processing chambers 31A through 31F.

After the wafer W undergoes the predetermined process in the vacuum processing chambers 31A through 31F, the wafer W is transferred out from the vacuum processing chambers 31A through 31F by the second transfer arms 32, and into the load lock chamber 22 or 23 under vacuum. Next, the load lock chamber 22 or 23 is pressurized to the atmospheric pressure, the wafer W is transferred back by the first transfer arm 26 to the carrier C from the load lock chamber 22 or 23 via the first transfer chamber 21.

Next, the arm cleaning process in this embodiment of the present invention is explained. This arm cleaning process is carried out after the wafer W is transferred plural times between the load lock chambers 22, 23 and the vacuum processing chambers 31A through 31F. For example, the arm cleaning process is carried out at a predetermined timing or at the time of maintenance.

First, the second transfer arms 32 (32A, 32B) are positioned at the home position, and the cleaning module 4 is moved upward from the accommodation position to the process position. Then, the holding arm 33 of the second transfer arm 32A is moved into the chassis 40 of the cleaning module 4. While the cleaning gas is supplied to the cleaning gas supplying pipe 43a by opening the valve V1, the valve V2 is opened so that the chassis 40 is evacuated by the vacuum evacuation unit 47. With this, the cleaning gas is sprayed onto the holding arm 33 from above, and film constituents attached on the holding arm 33 are peeled off and removed by the cleaning gas. The film constituents are evacuated along with the cleaning gas by the vacuum evacuation apparatus 2 through the evacuation port 45a, the evacuation bellows 45, and the evacuation passage 46. After the cleaning of the holding arm 33 of the second transfer arm 32A is completed in such a manner, the holding arm 33 of the second transfer arm 32B is subjected to the cleaning process. After the cleaning processes are completed for the second transfer arms 32A, 32B, the second transfer arms 32 are moved back to the home position, and the cleaning module 4 is moved downward and thus accommodated in the second concave portion 41.

Because the wafer holding area of the holding arms 33 is cleaned at a predetermined timing according to such an arm cleaning process, even if the remaining gas in the vacuum processing chambers 31A through 31F is adhered onto the second transfer arms 32, a film deposition onto the second transfer arms 32 can be reduced. Therefore, a cause for particle contamination due to the film deposited on the second transfer arms 32 can be reduced.

In addition, the cleaning module 4 is accommodated in the second concave portion 41 formed in a vacant portion of the bottom portion 30 of the second transfer chamber 3, namely a portion that becomes open when the second transfer arms 32 are positioned at the home position. Therefore, the cleaning module 4 is added without increasing the footprint of the second transfer chamber 3 and thus the vacuum processing apparatus 2.

In addition, the cleaning module 4 can be added by modifying a configuration of the bottom portion 30 of the second transfer chamber 3, and because the second transfer arms 32, the load lock chambers 22, 23, the vacuum processing chambers 31A through 31F or the like do not have to be modified, system changes are limited to a minimum, thereby facilitating a system design. In this case, when the second transfer chamber 3 is formed to extend long along the Y direction and the second transfer arms 32 are configured to be movable along the Y direction, a vacant area where the second transfer arm 32 is not located is formed in the transfer area of the second transfer arms 32. Therefore, the cleaning module 4 can be provided in the vacant area, which leads to an effective usage of space.

In addition, the cleaning module 4 is accommodated in the second concave portion 41 when the cleaning module 4 is not being used in order not to interfere with the second transfer arms 32 transferring the wafer W. With this, a normal wafer transfer can be carried out when the cleaning module 4 is not used. Therefore, a change in the transfer program is limited to minimum, which makes it possible to prepare a program corresponding to the vacuum processing apparatus 2 having the cleaning module 4.

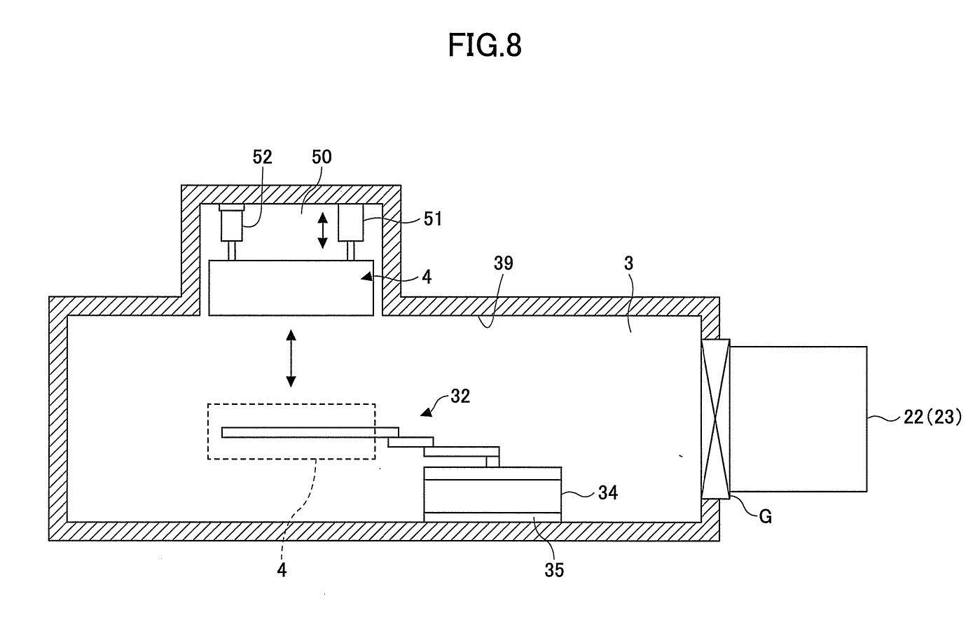

The cleaning module 4 may be configured to be accommodated in a concave portion 50 formed in a ceiling portion 39 of the second transfer chamber 3, as shown in FIG. 8, for example. In this example, the cleaning module 4 is connected at an upper surface to an elevation mechanism 51 provided in a ceiling portion of the concave portion 50. The cleaning module 4 is configured to be movable upward and downward between an accommodation position where the cleaning module 4 is accommodated in the concave portion 50 in order not to interfere with the second transfer arms 32 transferring the wafer W and a process position in the second transfer chamber 3, due to the elevation mechanism 51. “52” in FIG. 8 is an elevation guide. Other configurations are the same as those of the vacuum processing apparatus 2 shown in FIG. 4.

Next, another example of a process carried out with respect to the holding arms 33 in the auxiliary module is explained. First, the static electricity removal process for the holding arms 33 is carried out by providing an ionizer in a chassis of the auxiliary module, for example. With the ionizer, the static electricity removal process is carried out with respect to the holding arms 33. For example, the ionizer may be configured to supply an ion gas to the holding arms 33 introduced into the chassis 40. Alternatively, the ionizer may be configured so that the holding arms 33 can contact the ionizer. By removing static electricity of the holding arms 33, adsorption of particles may be reduced, and insulation breakdown of devices (in-process devices, or unfinished devices) fabricated on the wafer W can be reduced.

In addition, a position adjustment process for the holding arm 33 is carried out in such a manner that a position detection portion is provided, for example, in the auxiliary module, according to which position data of the holding arm 33 that has entered the chassis 40 are taken, and a position adjustment instruction is output from the control portion 100 to the driving mechanism of the substrate transfer unit, in accordance with the position data. As the position adjustment detection portion, a CCD camera that takes an image of the holding arm 33 for the purpose of position detection, or a sensor that carries out optical position detection of the holding arm 33 may be used. By carrying out the position adjustment of the holding arm 33 in such a manner, the wafer W is accurately transferred into or out from the vacuum processing chambers 31A through 31F and the preliminary vacuum chambers 22, 23, which makes it possible to reduce occurrence of accidents such as causing the wafer W to be dropped, or the holding arm 33 colliding with the wafer W, during in/out transfer of the wafer W.

Moreover, a temperature control process that heats or cools the holding arm 33 is carried out in such a manner that a temperature control unit is provided, for example, in the chassis 40, according to which the holding arm 33 that has been introduced is heated or cooled to adjust the holding arm 33 at a predetermined temperature. For example, the temperature control unit may be configured to blow inert gas whose temperature is controlled toward the holding arm 33 that has entered the chassis 40, or to cause the holding arm 33 to come in contact with a plate whose temperature is controlled. By carrying out the temperature control of the holding arm in such a manner, the unprocessed wafer W is preliminarily heated close to a process temperature, or the processed wafer W is preliminarily cooled, which makes it possible to shorten a time required to heat or cool the wafer W in the subsequent unit, thereby increasing throughput.

In the static electricity removal process and the temperature control process, when a gas is supplied in the chassis 40, an expandable gas supplying conduit and an evacuation bellows are preferably provided to address an upward or downward movement of the chassis in the same manner as the cleaning module 4

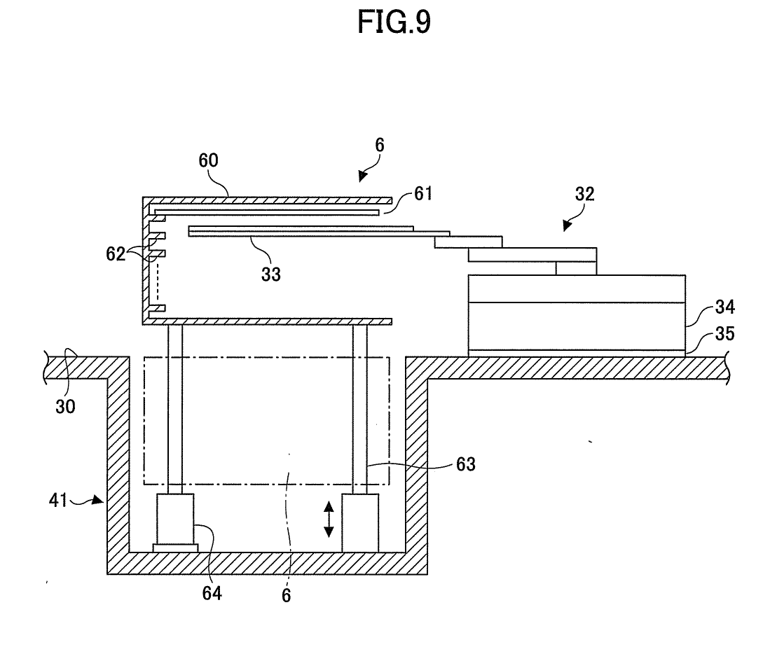

Next, another example of the embodiment is explained with reference to FIG. 9. In this example, a buffer module 6 on which plural (e.g., thirteen) wafers W are placed is provided as the auxiliary module. The buffer module 6 includes a chassis 60 having, for example, a shape of a flattened hollow rectangular cylinder having a square top view shape. The chassis 60 includes an opening 61 open toward the load lock chambers 22, 23. When the buffer module 60 is positioned inside the second transfer chamber 3, the holding arm 33 of the second transfer arm 32 can move into or out from the chassis 60 through the opening 61. Inside the chassis 60, plural holding portions 62, each of which holds a circumferential lower surface of the wafer W, are provided leaving a predetermined distance in a vertical direction between one another. The holding portions 62 correspond to a wafer receiving portion where the wafer W is placed. The chassis 60 so configured is movable upward and downward by an elevation mechanism 61 provided in the second concave portion 41 between an accommodation position where the chassis 60 is accommodated in the second concave portion 41 and a transfer position where the holding arm 33 transfers the wafer W into or out from the buffer module 6 in the second transfer chamber 3. When the buffer module 6 is at the accommodation position, the chassis 60 is accommodated in the second concave portion 41 in order not to interfere with the movement of the pedestal 34 of the second transfer arm 3. “64” in the drawing represents an elevation guide.

Such a buffer module 6 is used, for example, when interiors of the vacuum processing chambers 31A through 31F are cleaned. For example, when the vacuum processing chamber 31A is cleaned, first, the second transfer arms 32 are positioned at the home position. At this time, the second transfer arm 32A, which is one of the second transfer arms 32, holds the wafer W that has been processed in the vacuum processing chamber 31A, and the second transfer arm 32B, which is the other one of the second transfer arms 32, holds the unprocessed wafer W that is then transferred into the vacuum processing chamber 31A.

Then, the buffer module 6 is moved upward to the transfer position, and the unprocessed wafer W held by the second transfer arm 32B is transferred to the holding portion 62 of the buffer module 6. Next, the buffer module 6 is moved downward to the accommodation position, and then the processed wafer W is transferred by the second transfer arm 32A to the vacuum processing chamber 31B where the next process is carried out. Then, after the vacuum processing chamber 31A is cleaned, the second transfer arm 32B is located at the second position and then the buffer module 6 is moved upward to the transfer position. The unprocessed wafer W placed in the buffer module 6 is received by the second transfer arm 32B. Next, the buffer module 6 is moved downward and accommodated in the second concave portion 41, and then the unprocessed wafer W is transferred into the vacuum processing chamber 31A.

In such a manner, even when the wafer W cannot be transferred into the vacuum processing chambers 31A through 31F in order to clean the interiors of the vacuum processing chambers 31A through 31F, the unprocessed wafer W held by the second transfer arms 32 can be temporarily placed in the buffer module 6. Because one of the second transfer arms 32 is vacant, the wafer W processed in the vacuum processing chambers 31A through 31F can be transferred into the vacuum processing chambers 31A through 31F where the next process is carried out. With this, a situation is circumvented where the second transfer arms 32 are in a standby state while holding the two wafers W before and after the process carried out in one of the vacuum processing chambers 31A through 31F that is subjected to the cleaning, thereby avoiding a decrease in throughput.

Even in this example, the buffer module 6 is configured so that the buffer module 6 can be accommodated in the concave portion 50 formed in the ceiling portion 39 of the second transfer chamber 3, and movable upward and downward between an accommodation position in the concave portion 50 and a transfer position in the second transfer chamber 3.

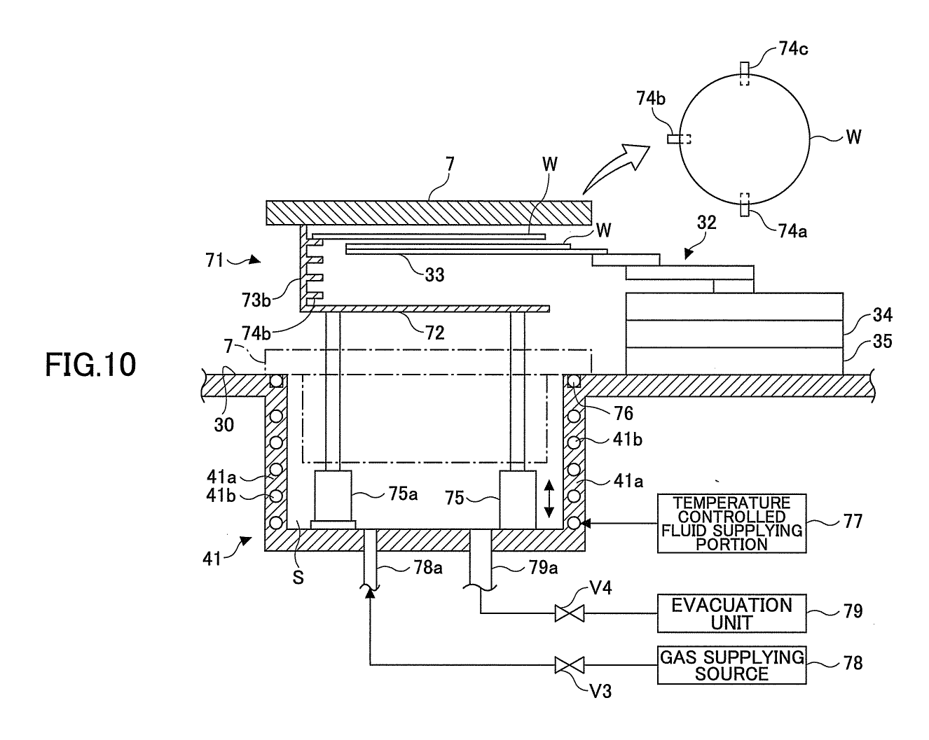

Next, another embodiment of the present invention is explained with reference to FIGS. 10 through 13. An auxiliary module in this embodiment is provided with a lid body 7 that can close the upper opening of the second concave portion 41 in an airtight manner and a wafer receiving portion where the wafer W is placed in a partitioned space S formed by the second concave portion 41 and the lid body 7. The wafer W is processed in the partitioned space S. “71” in the drawings represents a holding member for the wafer W as the wafer receiving portion. The holding member 71 is provided with, for example, a bottom plate 72 opposing the lid body 7, and plural (e.g., three) pillars 73a through 73c between the lid body 7 and the bottom plate 72. In the pillars 73a through 73c, holding portions 74a through 74c hold the corresponding wafers W leaving a predetermined distance between the wafers W, and circumferential edges of the wafers W are held by the corresponding holding portions 74a through 74c.

The lid body 7 and the holding member 71 are configured to be movable upward and downward in an integrated manner by a common elevation mechanism provided on a lower surface of the bottom plate 72 of the holding member 71. With this, the lid body 7 and the holding member 71 can be located in a position where the lid body 7 closes the second concave portion 41 in an airtight manner and a transfer position where the wafer W is transferred to or from the holding member 71 by the second transfer arms 32 that have been moved upward into the second transfer chamber 3. In FIG. 10, “75a” represents an elevation guide, and “76” represents an O-ring as a sealing member that closes the upper opening of the second concave portion 41 in an airtight manner. In addition, when the lid body 7 is at the position where the lid body 7 closes the second concave portion 41, an upper surface of the lid body 7 does not interfere with movement of the pedestal 34 of the second transfer arms 32, so that the pedestal 34 can move above the lid body 7.

Moreover, a flow passage 41b of a temperature control fluid is formed, for example, inside a sidewall 41a of the second concave portion 41, and the temperature control fluid whose temperature is controlled at a predetermined temperature circulates through the flow passage 41b from a temperature control fluid supplying portion 77. In addition, a gas supplying passage 78a that supplies inert gas (or N₂ gas) to the partitioned space S formed by the second concave portion 41 and the lid body 7 is connected to the second concave portion 41, and another end of the gas supplying passage 78a is connected to a gas supplying source 78 via a valve V3. Furthermore, the second concave portion 41 is provided with an evacuation passage 79a that evacuates the partitioned space S to vacuum, and another end of the evacuation passage 79a is connected to a vacuum evacuation unit 79 via a valve V4. The flow passage 41b of the temperature control fluid and the gas supplying portion composed of the gas supplying passage 78a and the gas supplying source 78 constitute a temperature control unit.

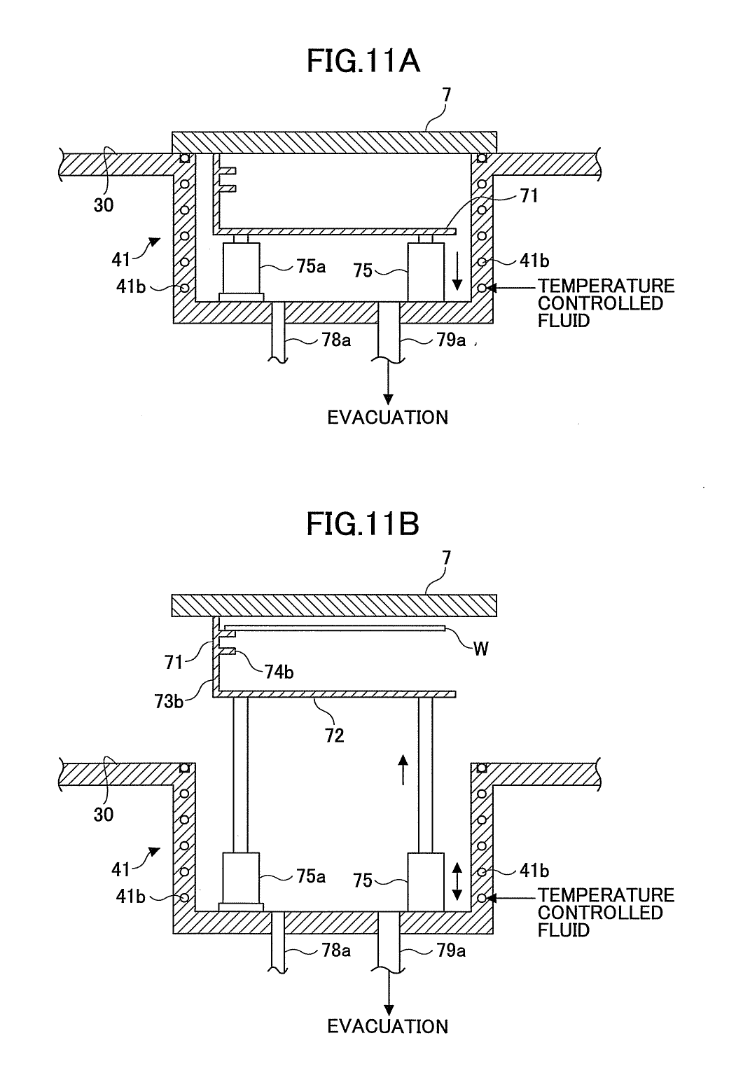

According to such a configuration, the temperature control process for the wafer W, for example, a process that preliminarily heats the wafer W before the wafer W undergoes a vacuum process in the vacuum processing chamber 31A through 31F is carried out in the partitioned space S. In the following, the preliminary heating process is explained with reference to FIGS. 11A through 13. First, as shown in FIG. 11A, the partitioned space S is formed by closing the upper opening of the second concave portion 41 with the lid body 7, and the partitioned space S is evacuated by the vacuum evacuation unit 79 (FIG. 10) through the evacuation passage 79a to the same pressure as a pressure in the second transfer chamber 3. At this time, the temperature control fluid whose temperature is controlled at a predetermined temperature is caused to flow through the flow passage 41b.

Next, after the second transfer arms 32 are positioned at the home position, the lid body 7 and the holding member 71 are moved upward to the transfer position as shown in FIG. 11B, and the wafer W is transferred to the holding member 71 by the second transfer arms 32. Then, the lid body 7 and the holding member 71 are moved downward, so that the lid body 7 closes the upper opening of the second concave portion 41 to form the partitioned space S. At this time, the partitioned space S is evacuated by the vacuum evacuation unit 79 (FIG. 10) through the evacuation passage 79a, and the temperature control fluid whose temperature is controlled at the predetermined temperature is supplied through the flow passage 41b.

Next, the evacuation of the partitioned space S is stopped, and the inert gas is supplied at a predetermined flow rate from the gas supplying source 78 to the partitioned space S through the gas supplying passage 78a, so that the partitioned space S is pressurized to substantially the atmospheric pressure. With this, the heat of the second concave portion 41 heated at a predetermined temperature by the temperature control fluid is transferred to the wafer W through the inert gas, so that the wafer W may be heated to a predetermined temperature, for example, about 200° C.

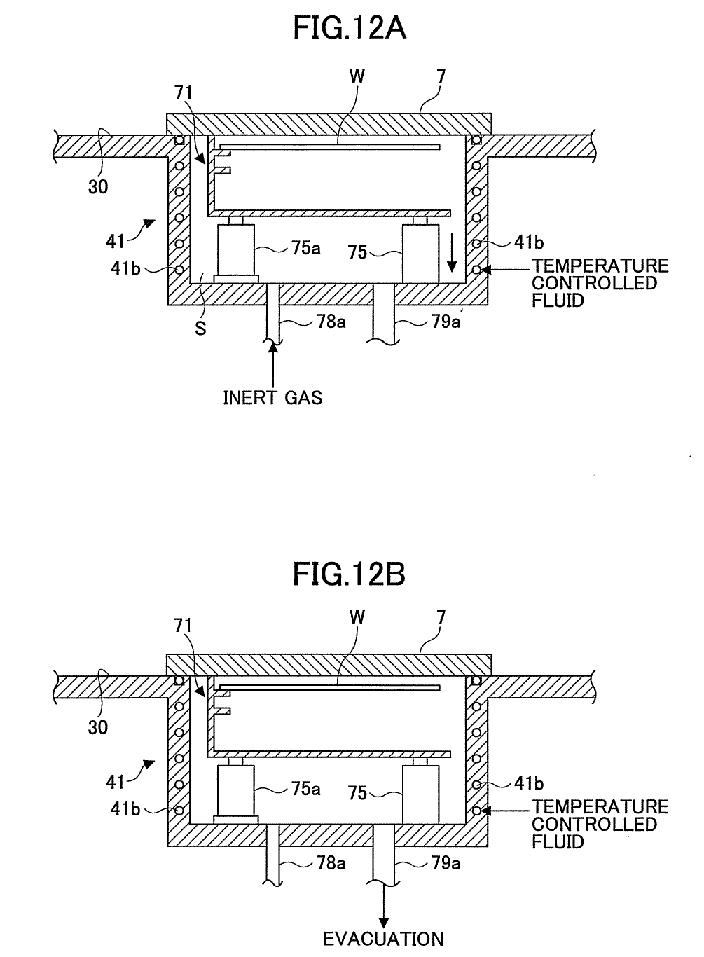

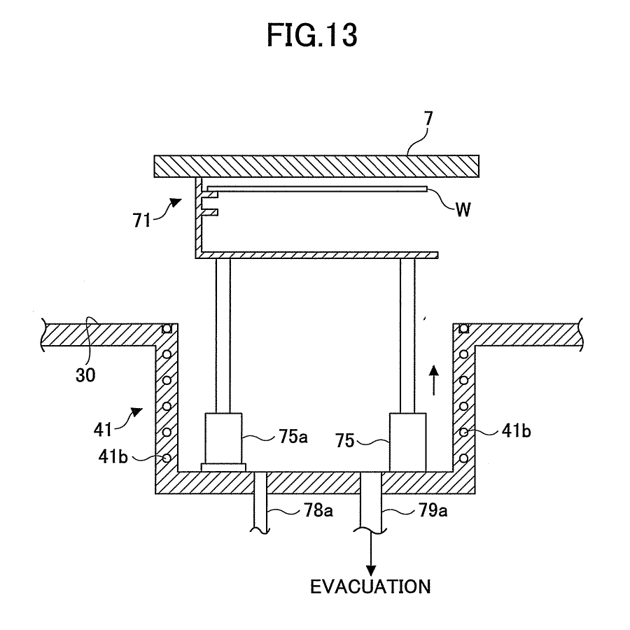

After this heating process is carried out, for example, for about 30 seconds, the supplying the inert gas to the partitioned space S and the temperature control fluid are stopped. Then, the partitioned space S is evacuated to vacuum by the vacuum evacuation unit 79 (FIG. 10) through the evacuation passage 79a, as shown in FIG. 12B, and thus the partitioned space S comes to have substantially the same pressure (reduced pressure) as the pressure of the second transfer chamber 3. Then, the lid body 7 and the holding member 71 are moved upward to the transfer position, as shown in FIG. 13, and the heated wafer W is transferred from the holding member 71 by the second transfer arms 32.

According to such a configuration, the second concave portion 41 can be used as a part of the process chamber because the lid body 7 that closes the upper opening of the second concave portion 41 in an airtight manner is provided in order to form the partitioned space S with the second concave portion 41 and the lid body 7, and a process is carried out with respect to the wafer W in the partitioned space S. Therefore, an additional function of processing the wafer W can be provided while avoiding an increased footprint of the vacuum processing apparatus 2. In addition, except for providing the additional function of processing the wafer W, because the other configurations such as the vacuum processing chambers 31A through 31F, the second transfer arms 32 and the like need not be modified, modifications of the system can be minimized while providing the additional function.

In this case, because the partitioned space S is configured in an airtight manner, and the gas supplying portion (the gas supplying passage 78a and the gas supplying source 78) and the vacuum evacuation unit 79 that evacuates the partitioned space S to vacuum are provided, pressure-control and supply/evacuation of the partitioned space S can be carried out independently from the second transfer chamber 3. Therefore, in this auxiliary module, the process for cooling the wafer W that has been vacuum-processed in the vacuum processing chambers 31A through 31F, the degassing process of the wafer W, and the like can be carried out, thereby enhancing a degree of freedom of the process carried out in the auxiliary module. Incidentally, a Peltier device or the like can be used as the temperature control unit.

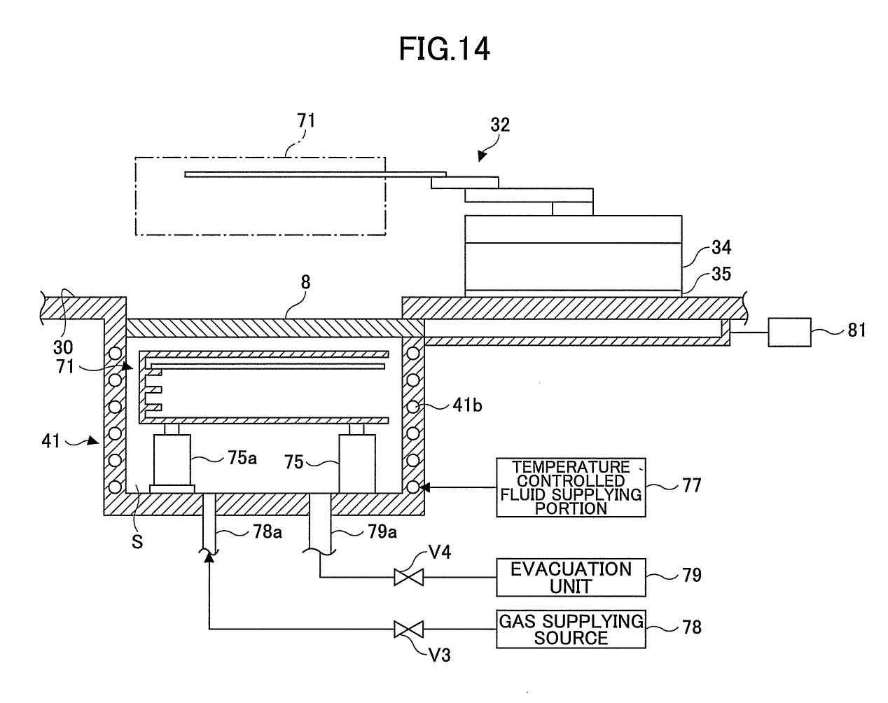

Next, another example of this embodiment is explained with reference to FIG. 14. In this example, the upper opening of the second concave portion 41 is openable/closable by sliding a lid body 8. Because the upper opening of the second concave portion 41 has a long side, for example, as long as about 500 mm, a pendular valve may be used as the lid body 8, for example. Alternatively, a gate valve may be used as the lid body 8. In the drawing, “81” represents a shifting mechanism of the lid body 8. The auxiliary module according to this embodiment is configured in the same manner as the auxiliary module shown in FIG. 10, except for only the holding member 71 being movable upward and downward by the elevation mechanism 75.

In this example, first the upper opening of the second concave portion 41 is closed by the lid body 8. After the partitioned space S formed by the second concave portion 41 and the lid body 8 is evacuated to the same pressure (reduced pressure) as the pressure in the second transfer chamber 3 by the vacuum evacuation unit 79, the lid body 8 is slid so that the upper opening of the second concave portion 41 is opened. Next, the holding member 71 is moved upward to the transfer position by the elevation mechanism 75, and the wafer W is transferred to the holding member 71 by the second transfer arm 32. Then, after the holding member is moved downward to a predetermined position in the second concave portion 41, the lid body 8 is slid so that the upper opening of the second concave portion 41 is closed, and the inert gas (or N2 gas) is supplied to the partitioned space S from the gas supplying source 78. With this, the wafer W is preliminarily heated through the inert gas by the heat of the temperature control fluid flowing through the flow passage 41b formed inside the sidewall 41a of the second concave portion 41. After the heating process is carried out for a predetermined period of time, supplying the inert gas to the partitioned space S is stopped, and the partitioned space S is evacuated to the same pressure (reduced pressure) as the pressure in the second transfer chamber 3. After this, the lid body 8 is opened; the holding member 71 is moved upward to the transfer position; and the process wafer W is transferred out by the second transfer arms 32.

In the examples shown in FIGS. 10 and 14, the lower opening of the concave portion 50 formed in the ceiling portion 39 of the second transfer chamber 3 may be closed by the lid body 7 or 8. In addition, the holding member 71 is movable upward and downward between the position in the concave portion 50 and the transfer position in the second transfer chamber 3, and a predetermined process may be carried out in the partitioned space S formed by the concave portion 50 and the lid body 7 or 8. In addition, the holding member 71 and the lid body 7 may be independently movable upward and downward.

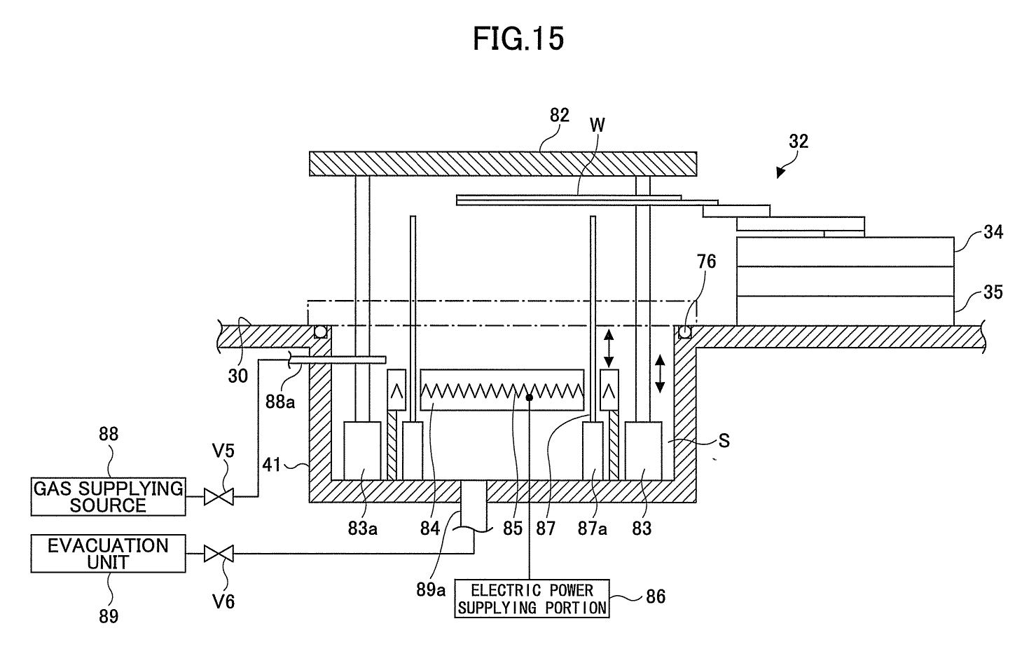

Next, yet another embodiment of the present invention is explained with reference to FIG. 15. Even in this embodiment, an auxiliary module is configured to include a lid body 82 that closes the upper opening of the second concave portion 41 in an airtight manner and a wafer receiving portion 84 on which the wafer W is placed in the partitioned space S formed by the second concave portion 41 and the lid body 82, so that the wafer W undergoes a predetermined process in the partitioned space S.

The lid body 82 is configured to be movable upward and downward between a position where the lid body 82 closes the upper opening of the second concave portion 41 in an airtight manner and a position above the transfer position in the second transfer chamber 3 (a position of the lid body 82 shown by a solid line in FIG. 15) by the elevatable mechanism 83. When the lid body 82 is at the position where the lid body 82 closes the second concave portion 41, the lid body 82 does not interfere with movement of the pedestal 34 of the second transfer arm 32, so that a lower surface of the pedestal 34 can move above the lid body 82. In FIG. 15, “83a” represents an elevation guide.

The wafer receiving portion 84 for the wafer W is provided inside the second concave portion 41, and a heater 85 is built into the wafer receiving portion 84, for example. “86” in the drawing represents an electric power supplying portion that supplies predetermined electric power to the heater 85. In this embodiment, the heater 85 and the electric power supplying portion 86 constitute a temperature control unit. In addition, elevation rods 87 that place the wafer W on the wafer receiving portion 84 and bring the wafer upward from the wafer receiving portion 84 are provided in the wafer receiving portion 84. The elevation rods 87 are configured to be movable upward and downward by the elevation mechanism 87a between a transfer position where the wafer W is received from the second transfer arms 32 or transferred to the second transfer arms 32 in the second transfer chamber 3 and a placing position where the wafer W is placed on the wafer receiving portion 84 (at this time upper ends of the elevation rods 87 are lower than an upper surface of the wafer receiving portion 84).

Moreover, a gas supplying passage 88a that supplies gas to the partitioned space S is provided, for example, above the wafer receiving portion 84 in the partitioned space S, and the other end of the gas supplying passage 88a is connected to a gas supplying source 88 via a valve V5. In addition, an evacuation passage 89a that evacuates the partitioned space S to vacuum is provided for the partitioned space S, and the other end of the evacuation passage 89a is connected to a vacuum evacuation unit 89 via a valve V6.

In this embodiment, a vacuum process such as a degassing process, a surface process, an annealing process, or an etching process for the wafer W can be carried out in the partitioned space S formed by the second concave portion 41 and the lid body 82. In other words, a process chamber where the vacuum process is carried out is configured by the second concave portion 41 and the lid body 82.

When the degassing process is carried out in this embodiment, first, the partitioned space S is formed by closing the upper opening of the second concave portion 41 with the lid body 82 in an airtight manner, and the partitioned space S is evacuated to the same pressure reduced pressure as the pressure in the second transfer chamber 3 by the vacuum evacuation unit 89. At this time, the wafer receiving portion 84 is heated at a predetermined temperature by the heater 85.

Next, the second transfer arms 32 are positioned at the home position; the lid body 82 is moved upward; and the second transfer arm 32 of which holding arm 33 holds the wafer W is moved to the transfer position, so that the wafer W is received by the elevation rods 87 from the second transfer arm 32. At this time, the lid body 82 is located above the transfer position. In addition, the elevation mechanism 83 of the lid body 82 is provided in order not to interfere with the transferring the wafer W between the second transfer arms 32 and the elevation rods 87 when the elevation rods 87 are at the transfer position. Then, the elevation rods 87 are moved downward, for example, to the placement position, which makes it possible to place the wafer W in the wafer receiving portion 84. After this, the upper opening of the second concave portion 41 is closed by moving the lid body 82 downward, so that the partitioned space S is formed by the lid body 82 and the second concave portion 41.

Next, a predetermined process gas is supplied to the partitioned space S through the gas supplying passage 88a, thereby causing the heat of the wafer receiving portion 84 to be transferred to the wafer W, so that the wafer W is heated at a predetermined temperature. With this, substances attached on the wafer W may be vaporized and removed. Because the partitioned space S is evacuated to vacuum while the process gas is supplied, vaporized component of the substances are evacuated along with the process gas to the outside, thereby avoiding the substances becoming re-attached on the wafer W. After such a degassing process is carried out for about 30 seconds, the partitioned space S is adjusted to the same pressure as the pressure in the second transfer chamber 3. Then, the lid body 82 is moved upward above the transfer position; the elevation rods 87 are moved upward to the transfer position; and the wafer W that has undergone the degassing process is transferred to the second transfer arm 32.

Even in such a configuration, the second concave portion 41 can be used as a part of the process chamber because the lid body 82 that closes the upper opening of the second concave portion 41 in an airtight manner is provided in order to form the partitioned space S with the second concave portion 41 and the lid body 82, and a process is carried out with respect to the wafer W in the partitioned space S. Therefore, an additional function of processing the wafer W can be provided while avoiding an increased footprint of the vacuum processing apparatus 2. In addition, except for providing the additional function of processing the wafer W, because the other configurations such as the vacuum processing chambers 31A through 31F, the second transfer arms 32 and the like need not be modified, modifications of the system can be minimized while providing the additional function.

Moreover, in this embodiment, a temperature of the wafer receiving portion 84 is adjusted by supplying the temperature-controlled fluid to the wafer receiving portion 84, and the heat of the wafer receiving portion 84 is transferred to the wafer W, so that the wafer W may undergo preliminary heating or cooling processes. In addition, in the same manner as shown in FIG. 10, a flow passage may be formed in the wall portion of the second concave portion 41, and a temperature-controlled fluid is caused to flow through it, so that the wafer W in the partitioned space S may be temperature-controlled. Furthermore, the wafer W may be held by the elevation rods 87 in the second concave portion 41, without providing the wafer receiving portion 84, and a predetermined process may be carried out.

Although the present invention has been described with reference to the above embodiments, the present invention is not limited to the disclosed embodiments, but may be variously modified or altered within the scope of the Claims. For example, the present invention is applicable to a configuration where the second transfer arms 32 are not slid. In addition, configurations of the buffer module 6, the holding member 71 provided on the lower surface of the lid body 7, and the wafer receiving portion 84 provided in the second concave portion 41 may be optionally modified, without being limited to the above examples. Moreover, the present invention is applicable to, for example, a vacuum processing apparatus where a flat panel display (FPD) substrate or the like is processed.

This international application claims priority based on Japanese Patent Application No. 2007-339987, filed on Dec. 28, 2007, and the entire contents of the Application No. 2007-339987 are incorporated herein by reference.

1. A vacuum processing apparatus comprising:
a preliminary vacuum chamber whose inner pressure is switchable between a normal pressure and a reduced pressure, wherein a substrate is transferred to or from the preliminary vacuum chamber;
plural vacuum processing chambers, wherein corresponding processes are carried out with respect to the substrate;
a vacuum transfer chamber to which the preliminary vacuum chamber and the plural vacuum processing chambers are connected, the vacuum transfer chamber including a substrate transfer mechanism that transfers the substrate between the preliminary vacuum chamber and the plural vacuum processing chambers, and a concave portion formed in a bottom portion or a ceiling portion of the vacuum transfer chamber;
an auxiliary module, wherein a predetermined process is carried out with respect to the substrate transfer mechanism; and
an elevation mechanism that moves the auxiliary module between a first position where the auxiliary module is accommodated in the concave portion so that the auxiliary module does not hinder the substrate transfer mechanism from transferring the substrate, and a second position where the substrate may be transferred to or from the auxiliary module by the substrate transfer mechanism.

2. The vacuum processing apparatus of claim 1, wherein the predetermined process carried out with respect to the substrate transfer mechanism is any one of a cleaning process for a holding arm of the substrate transfer mechanism, the holding arm holding the substrate, a static electricity removal process for the holding arm, and a position adjustment process for the holding arm.

3. A vacuum processing apparatus comprising:
a preliminary vacuum chamber whose inner pressure is switchable between a normal pressure and a reduced pressure, wherein a substrate is transferred to or from the preliminary vacuum chamber;
plural vacuum processing chambers, wherein corresponding processes are carried out on the substrate;
a vacuum transfer chamber to which the preliminary vacuum chamber and the plural vacuum processing chambers are connected, the vacuum transfer chamber including a substrate transfer mechanism that transfers the substrate between the preliminary vacuum chamber and the plural vacuum processing chambers, and a concave portion formed in a bottom portion or a ceiling portion of the vacuum transfer chamber;
an auxiliary module that may accommodate the substrate, wherein a predetermined process is carried out with respect to the substrate accommodated therein; and
an elevation mechanism that moves the auxiliary module between a first position where the auxiliary module is accommodated in the concave portion so that the auxiliary module does not hinder the substrate transfer mechanism from transferring the substrate, and a second position where the substrate may be transferred to or from the auxiliary module by the substrate transfer mechanism.

4. The vacuum processing apparatus of claim 3, wherein the auxiliary module comprises:
a lid body that is movable upward and downward between a third position where the concave portion is closed in an airtight manner and a fourth position where the lid body is projected into the vacuum transfer chamber by the elevation mechanism; and
a substrate receiving portion on which the substrate is placed, wherein the substrate receiving portion is movable upward and downward between a fifth position where the substrate is placed in the substrate receiving portion in a space defined by the concave portion and the lid body, and a sixth portion where the substrate is transferred between the substrate transfer mechanism and the substrate receiving portion.

5. The vacuum processing apparatus of claim 4, wherein the substrate receiving portion is moved upward or downward along with the lid body in an integrated manner.

6. The vacuum processing apparatus of claim 3, wherein the auxiliary module includes:
a lid body that is movable upward and downward between a third position where the concave portion is closed in an airtight manner and a fourth position where the lid body is projected into the vacuum transfer chamber by the elevation mechanism;
a substrate receiving portion arranged on a space defined by the concave portion and the lid body that closes the concave portion in an airtight manner, wherein the substrate is placed on the substrate receiving portion;
a transfer-in/out portion configured to be movable upward and downward so that the substrate may be transferred between the substrate receiving portion and the substrate transfer mechanism.

7. The vacuum processing apparatus of claim 4, wherein the auxiliary module comprises a process portion that carries out a process with respect to the substrate.

8. The vacuum processing apparatus of claim 7, wherein the process portion that carries out a process with respect to the substrate is a temperature control portion that controls a temperature of the substrate.

9. The vacuum processing apparatus of claim 8, wherein the auxiliary module includes a heating portion that heats the substrate.

10. The vacuum processing apparatus of claim 8, wherein the auxiliary module includes a cooling portion that cools the substrate.

11. The vacuum processing apparatus of claim 8, wherein the temperature control portion comprises:
a flow passage of a temperature control fluid, formed in a wall portion of the concave portion;
a gas supplying portion that supplies gas to a space defined by the concave portion and the lid body that closes the concave portion in an airtight manner; and
an evacuation portion that evacuates the space to vacuum.

12. The vacuum processing apparatus of claim 11, wherein a substance attached on the substrate is removed by vaporizing the substance attached on the substrate.

13. The vacuum processing apparatus of claim 1, wherein the substrate transfer mechanism comprises:
a pedestal provided in the vacuum transfer chamber in order to be movable along a guide rail provided in the vacuum transfer chamber; and
a holding arm for the substrate, the holding arm being provided in the pedestal in order to be rotatable and movable to and fro in a horizontal direction,
wherein a concave portion formed in a bottom portion of the vacuum transfer chamber may be arranged in an area where the concave portion does not interfere with the guide rail so that the pedestal does not interfere with the concave portion.

14. A vacuum processing method executed in the vacuum processing apparatus of claim 1, the vacuum processing method comprising the steps of:
accommodating the auxiliary module in the concave portion;
transferring the substrate into one vacuum processing chamber among the plural vacuum processing chambers using the substrate transfer mechanism;
carrying out a predetermined vacuum process with respect to the substrate in the one vacuum processing chamber;
causing the auxiliary module to project into the vacuum transfer chamber from the concave portion and moving the substrate transfer mechanism into the auxiliary module; and
carrying out the predetermined process with respect to the substrate transfer mechanism in the auxiliary module.

15. The vacuum processing method of claim 14, wherein any one of a cleaning process for a holding arm of the substrate transfer mechanism, the holding aim holding the substrate, a static electricity removal process for the holding arm, and a position adjustment process for the holding arm is carried out in the step of carrying out a predetermined process with respect to the substrate transfer mechanism in the auxiliary module.

16. A vacuum processing method executed in the vacuum processing apparatus of claim 3, the vacuum processing method comprising the steps of:
accommodating the auxiliary module in the concave portion;
transferring the substrate into one vacuum processing apparatus chamber among the plural vacuum processing chambers using the substrate transfer mechanism;
carrying out the predetermined vacuum process with respect to the substrate in the one vacuum processing chamber;
causing the auxiliary module to project into the vacuum transfer chamber from the concave portion and moving the substrate transfer mechanism into the auxiliary module; and
accommodating in the concave portion the auxiliary module to which the substrate is transferred.

17. The vacuum processing method of claim 16, wherein the step of moving the substrate transfer mechanism into the auxiliary module is carried out when an arbitrary vacuum processing chamber among the plural vacuum processing chambers is cleaned.

18. The vacuum processing method of claim 16, further comprising a step of carrying out the predetermined vacuum process with respect to the substrate in the auxiliary module accommodated in the concave portion.

19. The vacuum processing method of claim 18, wherein a temperature of the substrate is adjusted in the step of carrying out the predetermined vacuum process with respect to the substrate in the auxiliary module.

20. The vacuum processing method of claim 18, wherein a substance attached on the substrate is removed by vaporizing the substance attached on the substrate in the step of carrying out the predetermined vacuum process with respect to the substrate in the auxiliary module.

21. A computer readable storage medium storing a computer program that causes the vacuum processing apparatus of claim 1 to execute a vacuum processing method, the computer program comprising steps in order to perform the steps of:
accommodating the auxiliary module in the concave portion;
transferring the substrate into one vacuum processing chamber among the plural vacuum processing chambers using the substrate transfer mechanism;
carrying out the predetermined vacuum process with respect to the substrate in the one vacuum processing chamber;
causing the auxiliary module to project into the vacuum transfer chamber from the concave portion and moving the substrate transfer mechanism into the auxiliary module; and
carrying out a predetermined process with respect to the substrate transfer mechanism in the auxiliary module.

22. A computer readable storage medium storing a computer program that causes the vacuum processing apparatus of claim 3 to execute a vacuum processing method, the computer program comprising steps in order to perform the steps of:
accommodating the auxiliary module in the concave portion;
transferring the substrate into one vacuum processing chamber among the plural vacuum processing chambers using the substrate transfer mechanism;
carrying out a predetermined vacuum process with respect to the substrate in the one vacuum processing chamber;
causing the auxiliary module to project into the vacuum transfer chamber from the concave portion and moving the substrate transfer mechanism into the auxiliary module; and
accommodating in the concave portion the auxiliary module to which the substrate is transferred.
